(19) United States
(12) Patent Application Publication
(10) Pub. No.: US 2006/0049834 A1
(43) Pub. Date: Mar. 9, 2006

(54) Capacitance detection circuit and capacitance detection method

(76) Inventor: Yuichi Umeda, Miyagi-ken (JP)

Correspondence Address: BEYER WEAVER & THOMAS LLP, P.O. BOX 70250, OAKLAND, CA, 94612-0250, US

(21) Appl. No.: 11/192,818

(22) Filed: Jul. 29, 2005

(30) Foreign Application Priority Data
Sep. 6, 2004 (JP) 2004-258232

(51) Int. Cl. G01R 27/26

(52) U.S. Cl. 324/658

(57) ABSTRACT

A capacitance detection circuit in which detection wirings are arranged in such a manner as to intersect a plurality of driving wirings, and detection electrodes forming capacitances between the driving wirings and the detection wiring that intersect each other are formed within a sensor plane includes a column wiring driving device for driving the driving wirings; a detection wiring selection device for selecting predetermined detection wiring from among a plurality of detection wirings; a reference electrode arranged in the vicinity of the detection electrode, the reference electrode detecting the electrical potential of the piece to be detected as a reference potential; and a capacitance computation section for determining a voltage value corresponding to the capacitance change on the basis of the reference potential and the detection potential determined from the electrical current corresponding to the capacitance of the detection electrode.

### BACKGROUND OF THE INVENTION

1. Field of the Invention

The present invention relates to a capacitance detection circuit for detecting irregularities of a piece to be detected, such as a fingerprint of a finger, and to a capacitance detection method for use therewith.

2. Description of the Related Art

Hitherto, as capacitance detecting sensors for detecting irregularities of a piece to be detected, capacitance detecting sensors for detecting an electrostatic capacitance between detection electrodes arranged in an array and a piece to be detected and for measuring a change in the capacitance by using a peripheral circuit have been proposed. For this capacitance detecting sensor, in a peripheral circuit for performing capacitance detection, for example, a charge amplifier circuit shown in FIG. 13 is often used (refer to, for example, Japanese Unexamined Patent Application Publication No. 2001-46359).

The charge amplifier circuit has a function for conversion into a voltage value corresponding to a capacitance change without being affected by the parasitic capacitance of the row wiring that transmits a signal to the peripheral circuit when there is no influence of external noise. However, in the charge amplifier circuit, when there is an influence of noise from a piece to be detected, noise that is input from the piece to be detected is input from all the detection capacitance elements formed by the row wiring connected to the charge amplifier circuit, and the output voltage Vo of the charge amplifier circuit becomes a voltage value expressed by equation (1) shown below:
Vo=−Cx·Vi/Cf−Cn·Vn/Cf (1)
where Vi is an input voltage, Vn is a voltage value of noise that is input, Cx is a capacitance value of the selected detection capacitance element, Cn is a parasitic capacitance value, and Cf is a capacitance value of feedback capacitance in the charge amplifier circuit.

In comparison, as a method for reducing the influence of noise that is input from the piece to be detected, a method for reliably achieving grounding of the piece to be detected is conceived. For example, the method (see FIG. 14) for forming a grounding electrode around a detection electrode 105 on the surface of a capacitance detecting sensor 105a has been proposed as countermeasures against static electricity, which protect the capacitance detection elements from electro-static damage (refer to, for example, Japanese Unexamined Patent Application Publication No. 2001-324303). However, it is considered that the configuration for protection against electro-static damage has the advantage of reducing the influence of noise that is input from the piece to be detected.

However, in the capacitance detecting sensor described in Japanese Unexamined Patent Application Publication No. 2001-46359, many capacitance detection elements are connected to the column wirings for transmitting electrical current corresponding to a change in capacitance to a detection circuit. Therefore, the usually considered parasitic capacitance Cn becomes several hundred times as great as the capacitance value Cx of one capacitance detection element to be actually measured. As a result, if the sensitivity of the charge amplifier circuit is increased to detect a very small capacitance change, the signal output from the charge amplifier circuit changes due to the voltage value due to noise that is mixed in via the parasitic capacitance Cn from the piece to be detected, presenting the drawback that the measurement of the capacitance of the capacitance detection element to be measured cannot be accurately performed.

Furthermore, as shown in the figures, the capacitance detecting sensor described in the Japanese Unexamined Patent Application Publication No. 2001-324303 cannot be grounded in such a manner that noise from the piece to be detected is brought to a level close to “0” due to the limited grounding area.

### SUMMARY OF THE INVENTION

The present invention has been made in view of such circumstances. An object of the present invention is to provide a capacitance detecting sensor for performing satisfactory shape detection without being affected by noise from a piece to be detected.

To achieve the above-mentioned object, in one aspect, the present invention provides a capacitance detection circuit in which detection wirings are arranged in such a manner as to intersect a plurality of driving wirings, detection electrodes forming capacitances between the driving wirings and the detection wirings that intersect each other are formed within a sensor plane, and a capacitance change of the detection electrode, which changes due to a piece to be detected, is detected as a voltage value, the capacitance detection circuit including: column wiring driving means for driving the driving wirings; detection wiring selection means for selecting predetermined detection wiring from among a plurality of detection wirings; a reference electrode arranged in the vicinity of the detection electrode, the reference electrode detecting the electrical potential of the piece to be detected as a reference potential; and a capacitance computation section for determining a voltage value corresponding to the capacitance change on the basis of the reference potential and the detection potential determined from the electrical current corresponding to the capacitance of the detection electrode.

In another aspect, the present invention provides a capacitance detection method in which detection wirings are arranged in such a manner as to intersect a plurality of driving wirings, detection electrodes forming capacitances between the driving wirings and the detection wirings that intersect each other are formed within a sensor plane, and a capacitance change of the detection electrode, which changes due to a piece to be detected, is detected as a voltage value, the capacitance detection method including the steps of: driving the driving wirings; selecting predetermined detection wiring from among a plurality of detection wirings; detecting the electrical potential of the piece to be detected as a reference potential by a reference electrode arranged in the neighborhood of the detection electrode; and determining a voltage value corresponding to the capacitance change on the basis of the reference potential and the detection potential determined from the electrical current corresponding to the capacitance of the detection electrode.

With this configuration, in the capacitance detecting sensor in accordance with the present invention, as a result of arranging a reference electrode around a detection electrode, as a reference potential containing a voltage due to noise that is input from a piece to be detected, the difference between the measured voltage measured by the detection electrode and the reference potential is computed. Since a voltage nearly equal to noise applied to the detection wiring is contained in the reference potential of the reference electrode, it is possible to substantially cancel the influence of a noise voltage to be superposed onto the measured voltage, and it is possible to measure the voltage due to the electrostatic capacitance between the piece to be detected and the detection electrode with higher accuracy than that in a conventional example.

In the capacitance detection circuit in accordance with the present invention, preferably, the detection wiring selection means selects first and second detection wirings, and the capacitance computation section includes: detection potential output means for differentially amplifying the current value corresponding to the capacitance of each detection electrode corresponding to the first and second detection wirings and for outputting the value as the detection potential; and computation means for determining a voltage value corresponding to the capacitance of each intersection part on the basis of the detection potential that is input in a time series manner.

With this configuration, in the capacitance detection circuit in accordance with the present invention, the detection potential obtained by differentially amplifying the measured voltage based on the electrical current of the corresponding one of the detection wirings and the measured voltage based on the electrical current of the simultaneously selected other detection wiring is detected, and the capacitance change of the selected detection electrode is sequentially separated to measurement data for each detection wiring through predetermined computations. As a result, an influence of extraneous noise that propagates from a human body, etc., is assumed to be in-phase components and can be effectively reduced. Moreover, it becomes possible to eliminate an influence of the difference in the capacitance for each detection wiring, an influence of the extension of wirings, and an influence of the variations of the parasitic resistance and the parasitic capacitance of a first-stage selector.

In the capacitance detection circuit in accordance with the present invention, preferably, in a detection period, the detection wiring selection means selects reference potential detection wiring to which the reference electrode is connected as the first detection wiring and detection wiring in the vicinity of the reference potential detection wiring as the second detection wiring, and thereafter selects detection wirings in the neighborhood from among the plurality of detection wiring as first and second detection wirings, and the computation means cumulatively adds the detection potentials that are input in a time series manner in order to determine a voltage value corresponding to the capacitance in the intersection part.

In the capacitance detection circuit in accordance with the present invention, preferably, continuously to the reference potential detection wiring and the detection wiring in the neighborhood of the reference potential detection wiring selected respectively as the first and second detection wirings in the detection period, the detection wiring selection means selects detection wirings in the neighborhood in sequence as the first and second detection wirings.

In the capacitance detection circuit in accordance with the present invention, preferably, a plurality of differential amplifiers for determining the detection potential on the basis of the electrical current flowing through the first detection wiring and the second detection wiring are provided for each detection wiring through which differential amplification is performed, a predetermined differential amplifier determines the detection potential between the reference potential detection wiring and the first detection wiring, and the plurality of the other differential amplifiers determine the detection potential between the detection wirings including the first detection wiring.

With this configuration, in the measurement of the capacitance change of the selected detection wiring due to the fact that a piece to be detected comes nearby, by using reference potential detection wiring, the capacitance detection circuit in accordance with the present invention determines the difference value of the measured voltages between reference potential detection wiring and predetermined detection wiring using a differential amplifier. Hereafter, the capacitance detection circuit determines the difference value of the measured voltages between detection wirings in the neighborhood in such a manner that the difference value between the measured voltages of the first detection wiring and the second detection wiring in the vicinity of the first detection wiring is determined . . . , and cumulatively adds these values in sequence. Thus, it is possible to easily obtain a measured voltage corresponding to each detection wiring by a simple computation process on the basis of the voltage value corresponding to the reference potential and the added voltage value for each cumulative addition. In addition, it becomes possible to remove a noise voltage to be superposed onto the detection signal of the detection wiring.

In the capacitance detection circuit in accordance with the present invention, preferably, the plurality of the detection wirings are divided into a group of detection wirings, the detection wiring selection means is provided for each group of the detection wirings, and the computation means determines the voltage value corresponding to the capacitance of the detection electrode by using, as the unit, each detection wiring selected by the detection wiring selection means.

With this configuration, the capacitance detection circuit in accordance with the present invention does not need to provide charge amplifiers corresponding to the number of the row wirings. Consequently, it becomes possible to reduce the circuit scale and the consumption of electrical current and possible to reduce an influence of the error voltage due to the accumulation of errors due to cumulative addition when determining the voltage value corresponding to the capacitance of each detection electrode and due to the accumulation of noise voltage that cannot be completely removed even by a differential computation using a reference potential.

That is, in the capacitance detection circuit in accordance with the present invention, the cumulative addition of the difference value of the measurement data between detection wirings in the neighborhood is made to fall within the range of the column wiring group. As a result, the cumulative value of detection errors contained in the difference value, etc., is reduced, and it is possible to measure the capacitance of the intersection part with higher accuracy.

In the capacitance detection circuit in accordance with the present invention, preferably, a plurality of the reference electrodes are provided on the sensor plane, and the reference electrodes are electrically connected to each other.

With this configuration, in the capacitance detection circuit in accordance with the present invention, variations of the reference potential depending on the location where the reference electrode is disposed can be reduced. Thus, even if the piece to be detected contacts any reference electrode, the reference potential can be used as a reference potential for all the detection electrodes on the sensor plane.

Since the fingerprint sensor in accordance with the present invention has a capacitance detection circuit described in the foregoing, it is possible to detect the capacitance change of the detection electrode and possible to detect the shape of a fingerprint with high accuracy.

As described in the foregoing, according to the capacitance detection circuit in accordance with the present invention, both the configuration of a reference electrode for detecting the electrical potential of a piece to be detected as a reference potential and the configuration for separating the capacitance of the detection electrode in the driven detection wiring on the basis of the reference potential and the cumulative value of the difference values between detection wirings in the neighborhood are provided. As a result, the capacitance detection circuit has a high resolution, and the advantage capable of detecting a very small capacitance value of the detection electrode and the amount of the change of the capacitance of the detection electrode due to the fact that a piece to be detected comes nearby with high accuracy can be obtained.

Furthermore, according to the capacitance detection circuit in accordance with the present invention, a reference by which a difference value with the output of each detection wiring is calculated is provided as reference potential detection wiring separately to the detection wiring in place of differential detection between detection wirings in the neighborhood in order to remove noise components input from a human body, etc. As a result, it is possible to obtain the advantage that the DC level of capacitance detection is stabilized and the capacitance can be measured with high accuracy.

### BRIEF DESCRIPTION OF THE DRAWINGS

FIG. 1 is a plan view showing an example of the configuration of a capacitance detecting sensor according to an embodiment of the present invention;

FIG. 2 is a conceptual view showing the cross section along the line II-II in the capacitance detecting sensor in FIG. 1;

FIG. 3 is a detailed view showing the configuration of a detection electrode 101 in the capacitance detecting sensor of FIG. 1;

FIG. 4 is a line sectional view showing the cross section along the line IV-IV in the detection electrode 101 of FIG. 3;

FIG. 5 is a block diagram showing an example of the configuration of a fingerprint sensor using a capacitance detection circuit according to the embodiment of the present invention and a capacitance detecting sensor of FIG. 1;

FIG. 6 is a conceptual view illustrating an example of the configuration of a sensor element 55 formed in the intersection part between driving wiring 112 and detection wiring 113 in a sensor section 1, which is an area sensor (two-dimensional sensor) of FIG. 5;

FIG. 7 is a block diagram showing an example of the configuration of a charge amplifier circuit 6 of FIG. 5;

FIG. 8 is a block diagram showing an example of the configuration of a reference potential input circuit 8 of FIG. 5;

FIG. 9 is a block diagram showing an example of the configuration of a differential detection circuit 7 of FIG. 5;

FIGS. 10A, 10B, and 10C are block diagrams showing an example of the configuration of a first-stage selector circuit 5 of FIG. 5;

FIG. 11 is a waveform chart illustrating the operation of a differential amplifier 121 of FIG. 7 and a differential amplifier 122 of FIG. 8;

FIG. 12 is a plan view of another example of the configuration of a capacitance detecting sensor according to. the embodiment of the present invention;

FIG. 13 is a conceptual view showing the configuration of a charge amplifier circuit used in the capacitance detecting sensor of a conventional example; and

FIG. 14 is a plan view showing the plane configuration of a conventional capacitance detecting sensor.

### DESCRIPTION OF THE PREFERRED EMBODIMENTS

A capacitance detection circuit of the present invention is a capacitance detection circuit in which detection wirings are arranged in such a manner as to intersect a plurality of driving wirings, detection electrodes forming capacitances between the driving wirings and the detection wirings that intersect each other are formed within a sensor plane, and a capacitance change of the detection electrode, which changes due to a piece to be detected, is detected as a voltage value, the capacitance detection circuit including: column wiring driving means for driving the driving wirings; detection wiring selection means for selecting predetermined detection wiring from among a plurality of detection wirings; a reference electrode arranged in the vicinity of the detection electrode, the reference electrode detecting the electrical potential of the piece to be detected as a reference potential; and a capacitance computation section for determining a voltage value corresponding to the capacitance change on the basis of the reference potential and the detection potential determined from the electrical current corresponding to the capacitance of the detection electrode.

The capacitance detecting sensor is formed in such a way that row wirings and column wirings are arranged in a matrix on a substrate, and irregularities of a piece to be detected are detected on the basis of a change in the capacitance between the two wirings in the intersection parts of the driving wirings and the detection wirings.

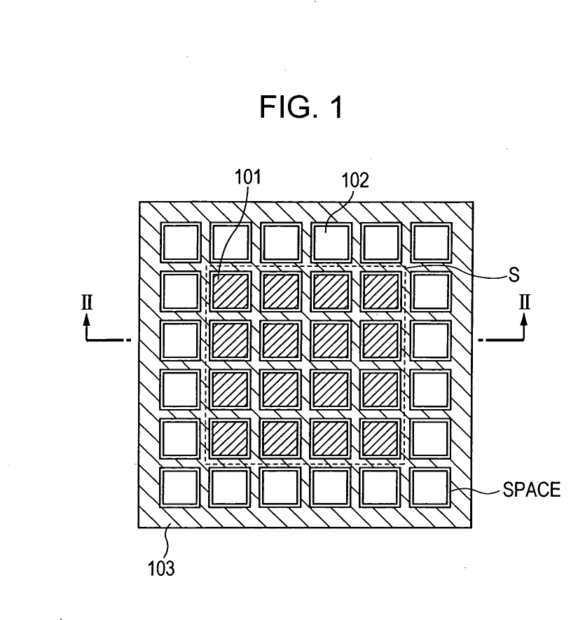

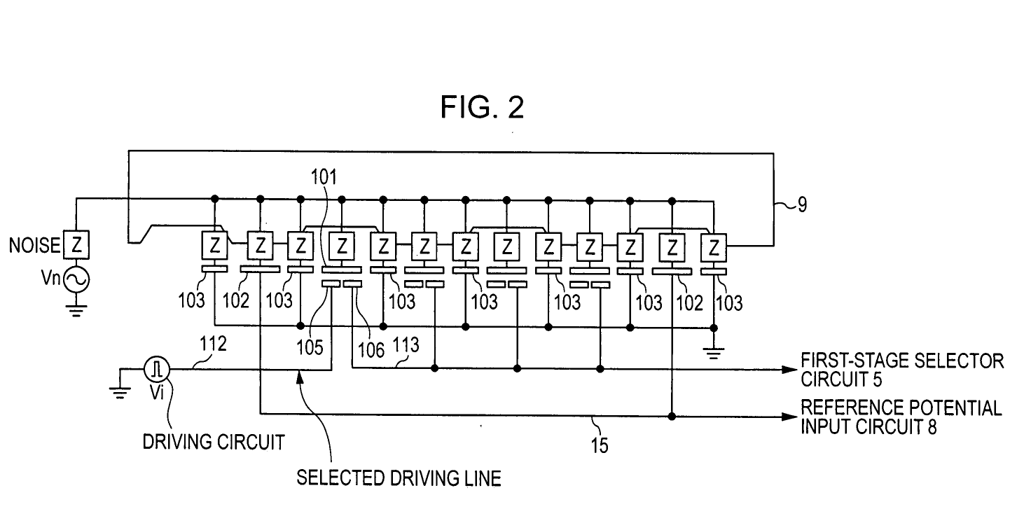

Referring to the drawings, a description will now be given below of a capacitance detecting sensor according to an embodiment of the present invention. FIG. 1 is a conceptual view showing the configuration in plan view of an example of the configuration of the embodiment. FIG. 2 is a conceptual view showing the cross section along the line II-II in FIG. 1.

In FIG. 1, a detection section S is provided with n×m (n and m are natural numbers and are 2 or more) detection electrodes 101 at a predetermined pitch, for example, 50 μm. A plurality of reference electrodes 102 are provided at the same pitch as that of the detection electrodes 101 around the provided detection section S (here, the reference electrodes 102 are provided in one line above and below and to the left and right of the detection section S, but may be provided in plural lines).

The periphery of the detection electrodes 101 and the reference electrodes 102 is surrounded by a grounding electrode 103 provided with a predetermined space in between (spatially insulated so as not to be electrically connected). Here, all the reference electrodes 102 are disposed so as to be electrically connected.

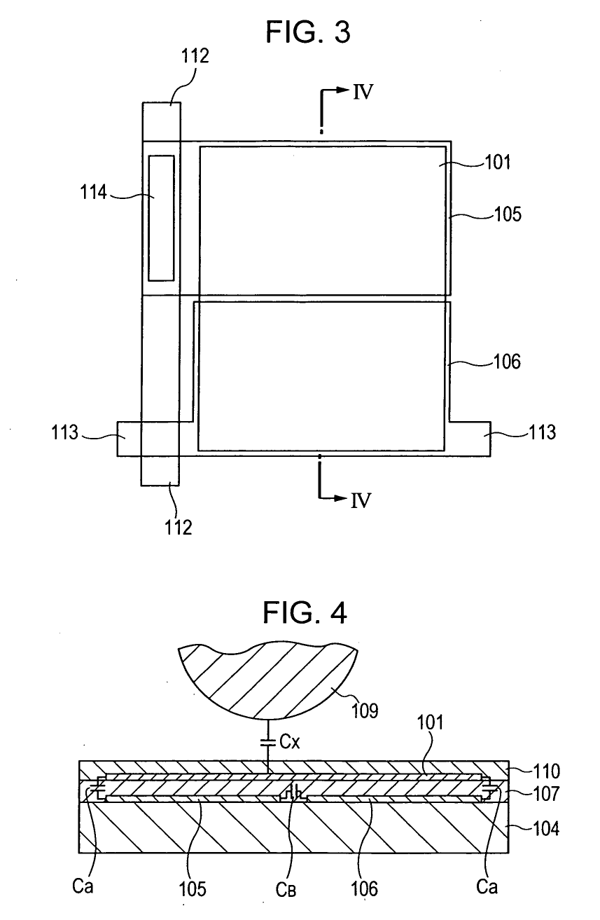

More specifically, the capacitance detecting sensor used in the present invention is one example of capacitance detecting sensors that do not have a switching element formed by a transistor, etc. and that operate in accordance with a control signal that is externally applied to driving wirings and detection wirings. As shown in FIG. 3 showing the enlarged detection electrode 101 of FIG. 1 and as shown in FIG. 4, which is a line sectional view along the line IV-IV in FIG. 3, driving wiring 112 and detection wiring 113 are arranged in a matrix on a sensor substrate 104. In the intersection parts of the driving wiring 112 and the detection wiring 113, a driving electrode 105 that extends from the driving wiring 112, a sensing electrode 106 that forms a pair with the driving electrode 105 and that extends from the detection wiring 113 in such a manner as to be adjacent to the driving electrode 105, and a floating detection electrode 101 arranged above the driving electrode 105 and the sensing electrode 106 via an interlayer insulation film 107 are provided, so that displacement current that flows from the driving electrode 105 to the sensing electrode 106, which changes in accordance with the distance between a piece 109 to be detected and the detection electrode 101 (the capacitive coupling state), is detected.

Here, as shown in FIG. 3, the driving electrode 105 and the sensing electrode 106 are formed so as to overlap the detection electrode 101, that is, they are capacitively coupled, so that displacement current flows from the driving electrode 105 to the sensing electrode 106 via the detection electrode 101.

In FIG. 3, it is preferable that the driving electrode 105 and the sensing electrode 106 be formed by the same layer and be capacitively coupled with the detection electrode 101. Furthermore, since the driving wiring 112 and the detection wiring 113 are formed from different wiring layers, the driving electrode 105 that extends from the driving wiring 112 is electrically connected by a contact 114.

On the top surface of the detection electrode 101, there are cases in which a passivation film 110 for protecting the detection electrode 101 is provided.

Referring back to FIG. 2, when a detection pulse is output from the driving circuit to the driving electrode 105, when a piece to be detected, for example, a finger 109, is sufficiently distant from the detection electrode 101 (when the finger 109 does not contact or the valley line of the finger 109 corresponds to the detection electrode 101), the capacitance Cx between the detection electrode 101 and the finger 109 is very small. As a result, a displacement current corresponding to the voltage of the detection pulse supplied to the driving electrode 105 flows to the sensing electrode 106 via the detection electrode 101. Here, Z in FIG. 2 indicates a predetermined impedance value.

On the other hand, when the piece to be detected, for example, the finger 109, is present in the neighborhood of the detection electrode 101 (when the crest line of the finger 109 corresponds to the detection electrode 101), the capacitance Cx between the detection electrode 101 and the finger 109 becomes a value that cannot be ignored (shielded by the electrical potential of the human body). A displacement current corresponding to the voltage of the detection pulse supplied to the driving electrode 105 flows to both the finger 109 and the sensing electrode 106 via the detection electrode 101, and thus the displacement current that flows to the sensing electrode 106 is decreased.

As a result, the degree of the coupling between the driving electrode 105 and the sensing electrode 106 changes in an analog manner in accordance with the distance between the valley line and the crest line in the finger 109, and the displacement current changes in association with the change of the degree of the coupling. Therefore, by detecting the amount of the change, the degree of the irregularities of the fingerprint is detected.

Next, with reference to the drawings, a description will be given of the above-described capacitance detection circuit for detecting a capacitance change of a sensor element according to the embodiment of the present invention. FIG. 5 is a block diagram showing an example of the configuration of the embodiment.

A sensor section 1 is formed by the sensor element described with reference to FIGS. 1 to 4, such that a plurality of driving wirings 112 of a driving wiring group 2 and a plurality of detection wirings 113 of a detection wiring group 3 intersect each other.

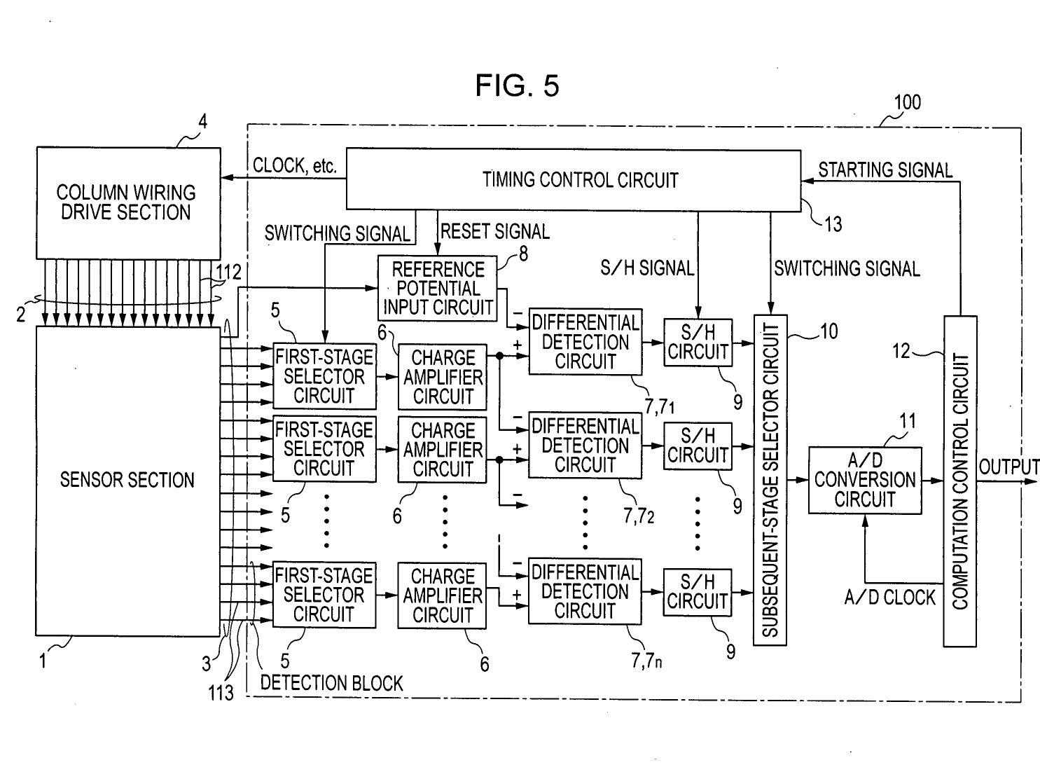

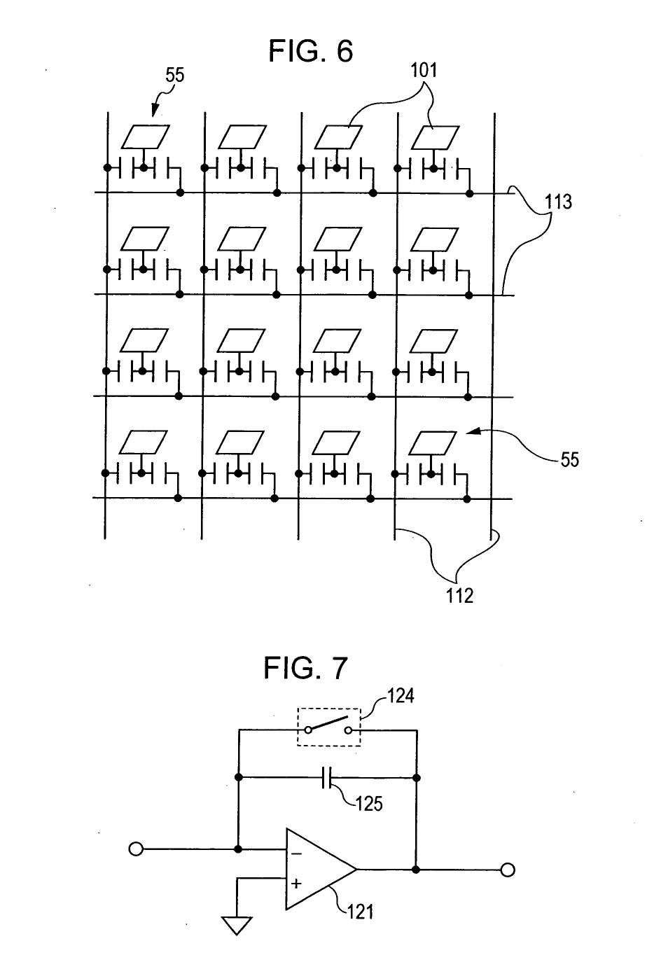

FIG. 6 is a conceptual view showing the matrix of capacitance elements (sensor elements) between the driving wirings 112 and the detection wirings 113 of the sensor section 1.

The sensor section 1 is formed of sensor elements 55, 55 . . . in a matrix, a column wiring driving section 4 is connected to the sensor section 1 via the driving wiring 112, and a capacitance detection circuit 100 is connected to the sensor section 1 via the detection wiring 113. That is, the driving wiring group 2 controlled by the column wiring driving section 4 and the detection wiring group 3 input to a first-stage selector circuit 5 for selecting the detection wiring 113 intersect each other, and the intersection part forms the sensor element 55.

The column wiring driving section 4 generates a driving pulse to be applied to the driving wiring 112 and supplies it to the driving wiring 112 of the driving wiring group 2.

The capacitance detection circuit 100 includes the first-stage selector circuit 5, a charge amplifier circuit 6, a differential detection circuit 7, a reference potential input circuit 8, a sample and hold circuit 9, a subsequent-stage selector circuit 10, an A/D conversion circuit 11, a computation control circuit 12, and a timing control circuit 13. The capacitance detection circuit 100 will now be described below.

The first-stage selector circuit 5 is provided for each of a plurality of detection wiring blocks in which the detection wiring group 3 is divided for each of the detection wirings 113, which are in units of a predetermined number of wires. The first-stage selector circuit 5 selects one of the detection wiring blocks and connects the selected detection wiring to the non-inverting input terminal of the differential detection circuit 7 via the charge amplifier circuit 6.

Usually, the irregularities of a fingerprint are said to be at a period of approximately 200 μm to 500 μm. When a difference voltage with the adjacent line is simply to be detected, the change of the signal due to the irregularities of the fingerprint becomes smaller. As a result, by appropriately setting the number of detection wirings 113 contained in each detection block, the detection wiring 113 is selected between detection blocks. Therefore, the distance of each detection wiring when the difference value is determined can be maintained, and the signal level of the difference value between adjacent detection blocks becomes comparatively large. Thus, this is advantageous in terms of the S/N ratio.

The charge amplifier circuit 6 is used to convert an electrical current into a voltage. The charge amplifier circuit 6 converts a displacement current of the sensor element 55, which is input from the first-stage selector circuit 5 and which flows to the detection wiring 113, into a voltage signal, and outputs it to the positive (+) terminal of the differential detection circuit 7 corresponding to the detection wiring block to which the charge amplifier circuit 6 belongs, that is, the non-inverting input terminal, and to the negative (−) terminal of the differential detection circuit 7 corresponding to the other detection wiring block in the neighborhood, that is, the inverting input terminal.

Here, as shown in FIG. 7, in the charge amplifier circuit 6, the output terminal of a differential amplifier 121 is connected in parallel with a feedback capacitance 125 (capacitance value Cf) and an analog switch 124 for discharging the electrical charge of the feedback capacitance 125 between the inverting input terminal and the output terminal, so that a predetermined voltage is input as a voltage reference to the non-inverting input terminal.

The analog switch 124 of the charge amplifier circuit 6 is normally in an off (open) state. When a reset signal is input thereto from the timing control circuit 13, the analog switch 124 is turned on to discharge the electrical charge of the feedback capacitance 125.

The differential detection circuit 7 detects a difference value between the voltage signal input from the charge amplifier circuit 6 corresponding to the other detection wiring block to the inverting input terminal and the voltage signal input from the charge amplifier circuit 6 corresponding to the detection wiring block of the differential detection circuit 7 to the non-inverting input terminal. That is, the differential detection circuit 7 outputs, as a differential signal, the difference between the voltages flowing through the detection wirings in the neighborhood.

The reference potential input circuit 8 accepts, as a reference potential, an electrical potential containing noise of the piece 109 to be detected in the neighborhood of the reference electrodes 102 shown in FIG. 1, and outputs the reference potential to one of the inverting input terminals of the differential detection circuits 7.

As has already been described, the reference electrodes 102 in FIG. 1 are such that they are not formed in a floating state, but all the reference electrodes 102 are electrically connected to reference potential detection wiring 15. For this reason, the electrical potential input to each reference electrode 102 is averaged as a result of being mixed, is hardly affected by the influence due to the irregularities of the piece 109 to be detected, and thus can be used as a reference potential.

Furthermore, if wiring resistance and wiring capacitance are not considered, the reference electrode 102 functions as wiring for directly transmitting the noise signal from the piece 109 to be detected.

At this time, the noise components superposed onto the detection signal input from the detection electrode 101 and the noise components input from the reference electrode 102 can be assumed to be in phase. However, since the configuration and the state of the propagation of the noise signal differ between the detection electrode 101 and the reference electrode 102 in the sensor section 1, the level of the noise components mixed in from the detection electrodes 101 in a floating state differs from the level of the noise signal input from the reference electrode 102.

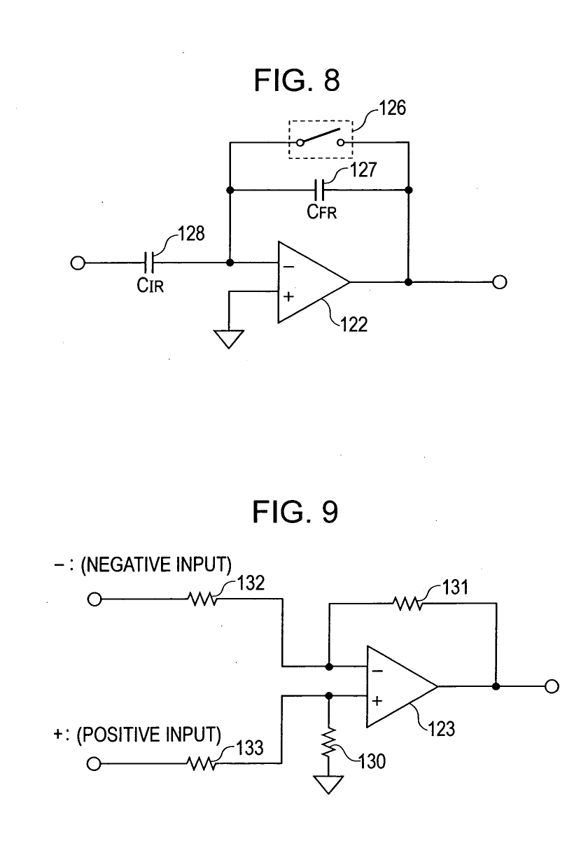

For this reason, the reference potential input circuit 8 converts an electrical current due to the noise signal from the reference electrode 102, which is input via an input capacitance 128 (capacitance value CIR) connected in series to the inverting input terminal. As shown in FIG. 8, a feedback capacitance 127 connected between the inverting input terminal and the output terminal in a differential amplifier 122 and an analog switch 126 for discharging the electrical charge of the feedback capacitance 127 (capacitance value CFR) are connected in parallel with each other, and a predetermined voltage is input as a voltage reference to the non-inverting input terminal.

As a result, in the reference potential input circuit 8, if the capacitance value of the feedback capacitance 127 is assumed to be the same as that of the feedback capacitance 125 of the charge amplifier circuit, by appropriately adjusting the ratio of the capacitance of the input capacitance 128 to that of the feedback capacitance 127, the voltage level of the noise components input from the detection electrode 101 and the voltage level of the noise components input from the reference electrode 102 can be made approximately the same in the stage where the voltage level is input to the differential detection circuit 7.

Furthermore, the analog switch 126 of the reference potential input circuit 8 is normally in an off (open) state. When a reset signal is input thereto from the timing control circuit 13, the analog switch 126 is turned on to discharge the electrical charge of the feedback capacitance 127.

As a result of a sample and hold (S/H) signal being input from the timing control circuit 13, the sample and hold circuit 9 temporarily holds the voltage level of the differential signal from the differential detection circuit 7 corresponding to the detection wiring block of the detection wiring 113 as voltage information in synchronization with the sample and hold signal.

The subsequent-stage selector circuit 10 sequentially selects the voltage information input from the plurality of the sample and hold circuits 9 one by one in accordance with the switching signal from the timing control circuit 13, and outputs it to the A/D conversion circuit 11 at the next stage.

The A/D conversion circuit 11 converts the voltage level of the voltage information output from the subsequent-stage selector circuit 10 into a digital value in synchronization with the A/D clock input from the computation control circuit 12, and outputs it to the computation control circuit 12.

The differential detection circuit 7 is provided in each of the plurality of detection wiring block units in which the detection wiring group 3 is divided. As has already been described, the differential detection circuit 7 detects a difference value between the voltage signal input from the charge amplifier circuit 6 corresponding to the other detection wiring block to the inverting input terminal and the voltage signal input from the charge amplifier circuit 6 corresponding to the detection wiring block of the differential detection circuit 7 to the non-inverting input terminal.

However, since the other corresponding detection wiring block is not present, the reference potential from the reference potential input circuit 8 for outputting the reference potential containing noise components is input to the inverting input terminal of the differential detection circuit 7 corresponding to the first detection wiring block. As a result, it is possible for the differential detection circuit 7 corresponding to the first detection wiring block to nearly eliminate, through differential detection, the noise components contained in the detection signal input from the charge amplifier circuit 6.

Here, in the differential detection circuit 7, as shown in FIG. 9, a predetermined voltage is input as a voltage reference to the non-inverting input terminal of a differential amplifier 123 via a resistor 130. The inverting input terminal thereof is connected to the output terminal via a resistor 131. A resistor 132 is connected in series to the inverting input terminal, and a resistor 133 is connected in series to the non-inverting input terminal. Based on this, the differential amplifier 123 amplifies the difference value between the voltage signal input via the resistor 132 and the voltage signal input via the resistor 133 on the basis of the degree of the amplification set by each of the resistance values of the resistors 130, 131, 132, and 133.

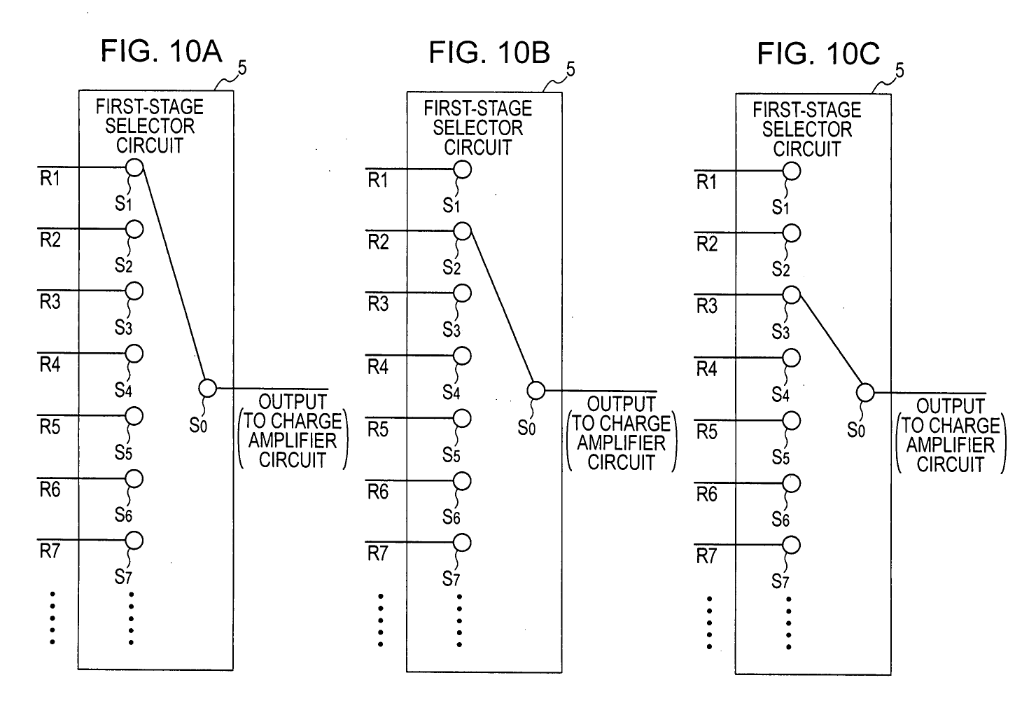

The first-stage selector circuit 5 is configured as shown in, for example, FIG. 10A. When the number of detection wirings 113 of the detection wiring group 3 is set at 256, if the detection wiring group 3 is divided into, for example, eight detection wiring blocks, the first-stage selector circuit 5 is provided for each of the detection wiring blocks. Consequently, eight first-stage selector circuits 5 are disposed in the capacitance detection circuit 100.

The first-stage selector circuits 5 have switching terminals S1, S2, S3, S4, S5, S6, S7 . . . to which are connected respectively detection wirings R1, R2, R3, R4, R5, R6, R7 . . . , which are the detection wirings 113 in the detection wiring block. In the first-stage selector circuit 5, the output terminal So is connected to the input terminal of the charge amplifier circuit 6 at the next stage. The output terminal So is connected in sequence to the switching terminals S1, S2, . . . , S7, . . . in accordance with a switching signal from the timing control circuit 13.

As a result, the first-stage selector circuit 5 sequentially outputs the detection signals of the detection wirings R1, R2, R3, R4, R5, R6, R7 . . . , in the detection wiring block to the charge amplifier circuit 6 at the next stage.

The timing control circuit 13 sequentially selects one detection wiring from each of the divided detection wiring blocks of the row detection wiring group 3. That is, these detection wirings are made to be detection wiring units to be measured in the neighborhood. Therefore, the timing control circuit 13 outputs the switching signal that is connected in a time series manner to the first-stage selector circuit 5 in the manner described above.

Next, referring to FIGS. 5 and FIGS. 10A to 10C, a description will be given below of an example of the operation of the capacitance detection circuit 100 according to the embodiment of the present invention.

It is assumed that a signal by which the computation control circuit 12 starts capacitance detection, that is, collects a fingerprint in the fingerprint sensor (the sensor section 1), is externally input.

In response, the computation control circuit 12 outputs, to the timing control circuit 13, a starting signal for instructing that the detection be started. Next, the timing control circuit 13 sequentially outputs a switching signal to the first-stage selector circuit 5 at predetermined detection intervals. Then,, the first-stage selector circuit 5 switches each switch provided therein in sequence in accordance with the switching signal that is input in a time series manner (made to correspond to the measurement that starts from each time).

As shown in FIG. 10A, at time t1 (in the measurement period that starts from time t1), each of the first-stage selector circuits 5 connects, to the output terminal So, a switching terminal S1 to which the detection wiring R1 in the detection wiring block is connected, and outputs the detection signal of the detection wiring R1 to the input terminal of the charge amplifier circuit 6. At this time, the first-stage selector circuit 5 allows the other switching terminals S2 to S7, . . . to be placed in a floating state or in a state in which they are connected to either a ground or the reference potential of the charge amplifier circuit 6.

Then, the timing control circuit 13 supplies a reset signal to the charge amplifier circuit 6, the differential detection circuit 7, and the column wiring driving section 4 in order to initialize the charge amplifier circuit 6, the differential detection circuit 7, and the column wiring driving section 4, so that the column wiring driving section 4 outputs a driving pulse to the driving wiring 112 in the driving wiring group 2.

Although not shown in the figures, the driving wiring group 2 is formed of a plurality of driving wirings 112, and these are selected in sequence in the measurement and a driving pulse is output.

Next, the timing control circuit 13 outputs a clock to the column wiring driving section 4 so that a driving pulse for driving the column wiring is output (rise to an H level). As a result, the column wiring driving section 4 outputs a driving pulse to a predetermined driving wiring 112 in the driving wiring group 2 in synchronization with the clock.

Then, each of the charge amplifier circuits 6 converts, into a voltage signal, a displacement current (detection current), which is input via the first-stage selector circuit 5, due to the voltage level of the applied driving pulse and the capacitance of the sensor element 55, and outputs the voltage signal as the measured voltage to the differential detection circuit 7 at the next stage.

In response, the differential detection circuit 7 inputs, to the non-inverting input terminal, the measured voltage corresponding to the detection signal of the selected detection wiring R1 in the detection wiring block corresponding to the differential detection circuit 7, inputs the measured voltage from the other detection wiring block, for example, the adjacent detection wiring block specified as a combination, to the inverting input terminal, performs predetermined amplification on the difference between the two voltages, and outputs the difference as a difference voltage.

Here, in the differential detection circuit 7 (for example, a differential detection circuit 7₁ in FIG. 5) excluded from the combination with the other detection wiring block, a reference potential output from the reference potential input circuit 8 is input to the inverting input terminal.

Next, after a predetermined time period has elapsed from the application of the driving pulse, the timing control circuit 13 outputs a sample and hold (S/H) signal to the sample and hold circuit 9. In response, the sample and hold circuit 9 temporarily holds the voltage level of the difference voltage output from the differential detection circuit 7 (stored as voltage information) in synchronization with the input sample and hold signal, and outputs a signal at the same voltage level as the voltage level of the difference voltage to the subsequent-stage selector circuit 10.

Then, the column wiring driving section 4 stops the output of the driving pulse in synchronization with the sample and hold signal (fall to an L level).

Next, the timing control circuit 13 sequentially selects the voltage information about the difference voltage output from each sample and hold circuit 9, and outputs, to the subsequent-stage selector circuit 10, a switching signal to be output to the A/D conversion circuit 11. At this point in time, the timing control circuit 13 outputs, to the subsequent-stage selector circuit 10, a switching signal for outputting the voltage information about the difference voltage from the differential detection circuit 7 (7₁) to the A/D conversion circuit 11. In response, the subsequent-stage selector circuit 10 selects and outputs a plurality of pieces of the voltage information about the difference voltages, which are input from each sample and hold circuit 9, in accordance with the switching signal that is input sequentially.

Next, after this switching signal is output and a predetermined time has passed, the timing control circuit 13 outputs a conversion signal to the computation control circuit 12.

Then, the computation control circuit 12 outputs an A/D clock to the A/D conversion circuit 11 in synchronization with the conversion signal. In response, the A/D conversion circuit 11 converts the voltage level input from the subsequent-stage selector circuit 10 into digital measured data in synchronization with the A/D clock, and outputs the measured data to the computation control circuit 12. The measured data at this time is:
d1=V1−Vref+Vofs
where V1 is a value such that the electrical current flowing through the row wiring R1 of the first detection wiring block, which is input to the non-inverting input terminal of the differential detection circuit 7 (7₁); Vref is the voltage value of the reference potential input from the reference potential input circuit 8; and Vofs is an offset value for representing output data using an 8-bit value (the number of bits is arbitrary) with no sign bit.

Next, the timing control circuit 13 sequentially selects the voltage information about the difference voltage output from each sample and hold circuit 9 and outputs, to the subsequent-stage selector circuit 10, a switching signal to be output to the A/D conversion circuit 11. At this point in time, the timing control circuit 13 outputs, to the subsequent-stage selector circuit 10, a switching signal for outputting the voltage information about the difference voltage from the differential detection circuit 7 (7₂) to the A/D conversion circuit 11. In response, the subsequent-stage selector circuit 10 selects and outputs the voltage information about the difference voltage, which is input from the sample and hold circuit 9 corresponding to the differential detection circuit 7 (7₂), in synchronization with the switching signal that is input in sequence.

Next, after the switching signal is output and a predetermined time has elapsed, the timing control circuit 13 outputs a conversion signal.

Then, the computation control circuit 12 outputs an A/D clock to the A/D conversion circuit 11 in synchronization with the conversion signal. In response, the A/D conversion circuit 11 converts the voltage level input from the subsequent-stage selector circuit 10 into digital measured data in synchronization with the A/D clock, and outputs the measured data to the computation control circuit 12. The measured data at this time is:
d2=V2−V1+Vofs
where V2 is a value such that the electrical current flowing through the detection wiring R1 of the second detection wiring block, which is input to the non-inverting input terminal of the differential detection circuit 7 (7₂), is converted into a voltage.

The timing control circuit 13 repeats the above-described processing by the number of times corresponding to the number (n) of the detection wiring blocks, in which the detection wiring group 3 is divided, so as to allow the computation control circuits 12 to obtain all the voltage information d of the difference voltage corresponding to the detection signal of the detection wiring R1 of each detection wiring block.

Next, as shown in FIG. 10B, at time t2 (in the measurement that starts from time t2), the timing control circuit 13 outputs a switching signal for outputting the detection signal of the detection wiring R2 in the detection wiring block to the first-stage selector circuit 5. In response, each of the first-stage selector circuits 5 connects the switching terminal S2, to which the detection wiring R2 in the detection wiring block is connected, to the output terminal So, and outputs the detection signal of the detection wiring R2 to the input terminal of the first-stage selector circuit 5 at the next stage. At this time, the first-stage selector circuit 5 allows the other switching terminals S1, S3 to S7, . . . to be placed in a floating state or in a state in which they are connected to either a ground or the reference potential of the charge amplifier circuit 6.

The switching operation of the subsequent-stage selector circuit 10 and the A/D conversion process of the A/D conversion circuit 11 may overlap each other in relation to time so that they are completed before the period in which the next detection voltage is sampled and held by the sample and hold circuit 9.

Next, the timing control circuit 13 performs the already described measurement process that is the same as that for the detection signal of the detection wiring R1 of each detection wiring block.

Also, at time t3 or later, the timing control circuit 13 performs the same processing. When the measurement process for all the detection wirings R1, . . . of each detection wiring block is completed, that is, when the detection wiring group 3 is divided into n detection wiring blocks and each detection wiring block is formed of m detection wirings R1 to Rm, the measurement for the detection wiring R1 of each detection wiring block is started. The driving wiring 112 is activated by the driving pulse in the measurement of each detection wiring up to the detection wiring Rm of each detection wiring block, and the measurement is performed.

In response, in the computation control circuit 12, measured data d1 to dn (×m) corresponding to the capacitance of each intersection part between the driving wiring 112 and the detection wirings R1 to Rn (×m) is stored in such a manner as to correspond to one driving wiring 112.

Here, if it is assumed that the driving wiring group 2 is formed of, for example, 255 driving wirings, also with respect to the other 254 driving wirings 112 in the driving wiring group 2, the above-described processing of the measurement for the combination of the reference potential and the detection signal of one detection wiring selected from each detection wiring block is performed to obtain measured data corresponding to each driving wiring, and the measured data is stored in the computation control circuit 12 in such a manner as to correspond to each driving wiring. Here, when all the measurements for the detection wirings contained in the detection wiring block are completed, the first-stage selector circuit 5 outputs a signal indicating the detection wiring measurement completion to the timing control circuit 13.

Then, when the signal indicating the detection wiring measurement completion is input, the timing control circuit 13 outputs a control signal by which the column wiring driving section 4 changes setting so as to output a driving pulse to the next driving wiring 112 before the next clock for the column wiring driving section 4.

In response, when a clock is input next, the timing control circuit 13 initializes the first-stage selector circuit 5 in synchronization with the clock so that a selection is newly made from the detection wiring R1 in each detection wiring block in which the detection wiring group 3 is divided. Similarly to when the first driving wiring 112 is driven, the timing control circuit 13 outputs a driving pulse to the second driving wiring 112 and performs the capacitance measurement for the sensor element 55 in the intersection part between the second driving wiring 112 and each detection wiring 113.

As described above, when the measurement of the difference voltage between the detection wirings in each detection wiring block of the detection wiring group 3 is completed as a result of sequentially driving the driving wirings over all the driving wirings 112 in the driving wiring group 2, the computation control circuit 12 performs measurements for determining voltage data corresponding to the capacitance of the sensor element 55 in each intersection part from the obtained measured data of the difference voltage.

Here, the computation control circuit 12 can determine voltage data corresponding to the capacitance in each intersection part between each column wiring and each row wiring by cumulatively adding the obtained measured data in driving wiring units for each combination of the detection wiring that is selected in sequence in each detection wiring block, for example, for each combination of the detection wiring R1 of each detection wiring block, for each combination of the detection wiring R2 of each detection wiring block, etc. For example, a computation corresponding to the capacitance of the sensor element 55 in the intersection part between the first driving wiring 112 and the detection wiring R1 in each detection wiring block is performed.

In the computation control circuit 12, if the voltage data of the reference potential is denoted as dr (that is, Vref), the measured data corresponding to the capacitance of the sensor element 55 in the intersection part between the driving wiring 112 and the first detection wiring block is denoted as d1 (measured data at time t1), and the voltage data to be determined in the intersection part is denoted as ds1, the voltage data ds1 can be expressed by
ds1=d1+dr=V1−Vref+Vofs+Vref=V1+Vofs

Similarly, if the measured data corresponding to the capacitance of the sensor element 55 in the intersection part between the driving wiring 112 and the detection wiring R1 in the second detection wiring block is denoted as d2 and if the measured data corresponding to the capacitance of the sensor element 55 in the intersection part between the driving wiring 112 and the detection wiring R1 in the third detection wiring block is denoted as d3, when the voltage data to be determined in each intersection part is denoted as ds2 and ds3, voltage values corresponding to the capacitance in each intersection part can be obtained by cumulatively adding the measured data in sequence as follows:
ds2=d2+ds1=V2−V1+V1+Vofs=V2+Vofs
ds3=d3+ds2=V3−V2+V2+Vofs=V3+Vofs

Next, in the above-described measurement, only the capacitance measurement at the rise of the driving pulse (shift from the second voltage to the first voltage; the first voltage>the second voltage) is performed. Alternatively, by performing measurements at the rise and the fall of the driving pulse (shift from the first voltage to the second voltage), an unwanted offset can be removed by time-related differential computation, and the calculation accuracy can be increased.

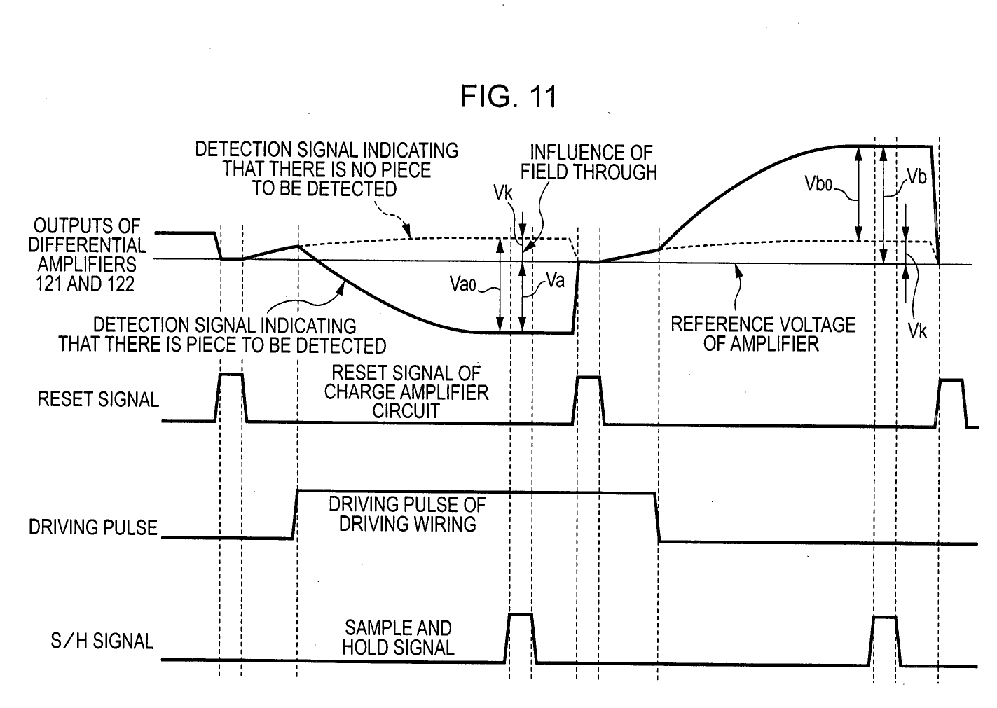

That is, in the measurement used only at the rise of the driving pulse, as shown in FIG. 11, even when the output OUT falls and rises from the reference potential of the amplifier, an offset Vk due to the field through current of the analog switch 124 (or 126) is generated in the +direction.

FIG. 11 is a waveform chart showing the operation of the differential amplifier 121 (or the differential amplifier 122 in the reference potential input circuit 8) in the charge amplifier circuit 6. As in this embodiment, when the capacitance value to be detected in the intersection part is from several tens to several hundreds of femto farads, the offset due to this field through current cannot be ignored.

In the measurement of the reference potential (the measurement in the differential amplifier 122),

−Vuref0=−Vuref−Vka is a voltage proportional to the capacitance value to be detected. However, the voltage to be measured is Vuref, and an err Vk due to the offset is contained in the voltage Vuref:
Vuref=Vuref0+Vka

Therefore, in this embodiment, the voltage Vdref when the capacitance CSR for which reference detection is to be made is discharged is also measured (intentionally, the reference electrodes 102 is not driven by the driving pulse, but since the driving wiring passes in the neighborhood, an effective capacitance CSR for which reference detection is to be made is generated).

Here, the voltage Vdref0 is a voltage proportional to the capacitance CSR, as shown below:
Vdref0=Vdref−Vka,
and the measured voltage becomes:
Vdref=Vdref0+Vka

Similarly, in the measurement for the detection wiring R1 in the first detection wiring block (the measurement in the differential amplifier 121),

−Vu10=−Vu1+Vkb becomes a voltage proportional to the capacitance value to be detected in the intersection part. The measured voltage is Vu1, and an error Vk due to an offset is contained in the voltage Vu1:
Vu1=Vu10+Vkb

Therefore, in this embodiment, the voltage Vd1 when the capacitance Cs to be detected is discharged is also measured. Here, a voltage Vd10 becomes a voltage proportional to the capacitance Cs, as shown below:
Vd10=Vd1−Vkb,
and the measured voltage becomes
Vd1=Vd10+Vkb.

Then, in the differential detection circuit 7, if the degree of amplification is set to “1” at the rise of the driving pulse, the following is obtained:

$$\begin{matrix}Vsu1 = Vu1 - Vuref + Vof \\ = Vu10 + Vkb - ( Vuref0 + Vka ) + Vof \\ = Vu10 - Vuref0 + Vkb - Vka + Vof\end{matrix}$$

where Vof is offset components in the A/D conversion circuit 11. Similarly, in the differential detection circuit 7, at the fall of the driving pulse, the following is obtained:

$$\begin{matrix}Vsd1 = Vd1 - Vdref + Vof \\ = Vd10 + Vkb - ( Vdref0 + Vka ) + Vof \\ = Vd10 - Vdref0 + Vkb - Vka + Vof\end{matrix}$$

The measured voltages Vsu1 and Vsd1 are held in sequence in the sample and hold circuit 9. Next, the A/D conversion circuit 11 performs A/D (analog/digital) conversion on the held voltages so as to be converted into measured data dsu1 and dsd1 for each measured voltage, and stores them in the memory of the computation control circuit 12.

Then, in the computation control circuit 12, a computation to obtain the following is performed:

$$\begin{matrix}d1 = dsd1 - dsu1 + Vofs \\ = ( Vd10 - Vdref0 + Vkb - Vka + Vof ) - \\ ( Vu10 - Vuref0 + Vkb - Vka + Vof ) + Vofs \\ = Vd10 - Vu10 - ( Vdref0 - Vuref0 ) + Vofs\end{matrix}$$

As a result, measured data d that does not contain an offset error due to field through current and an offset Vof during conversion in the A/D conversion circuit 11 can be obtained, where Vofs is an offset value for representing output data using an 8-bit value (the number of bits is arbitrary) with no sign bit.

The subsequent process for determining the voltage data ds corresponding to the capacitance of the sensor element 55 in each intersection part is the same as the already described method for performing cumulative addition.

In the above description, the capacitance detection circuit 100 temporarily holds the measured data obtained by the detection process, and after the capacitance measurements are completed for all the detection wirings in the driving wiring group 2, computations for determining voltage data are performed in such a manner as to correspond to the capacitance of the sensor element 55 in each intersection part in the sensor section 1. However, the capacitance detection circuit 100 may perform computations for determining voltage data in parallel with (almost simultaneously) the capacitance detection operation by cumulatively adding as desired the obtained measured data.

The setting of the capacitance value of the input capacitance 128 in the reference potential input circuit 8, that is, the gain set by the input capacitance 128 and the feedback capacitance 127, is determined as described below.

The gain of the charge amplifier circuit 6 with respect to the noise components induced in each selected detection wiring 113 is related to the substantial input capacitance Csn for the noise components based on the equation described below, which is the total value of the sum Csum of the capacitance value of each sensor element 55 and the capacitance Cext that is capacitively coupled from the other detection wirings 113 in the neighborhood:
Csn=Csum+Cext

Therefore, when the feedback capacitance of the charge amplifier circuit 6 is denoted as CF, the gain Gsn of noise induced in each detection wiring 113 is defined by the following equation:
Gsn=CF/Csn

When the reference electrodes 102 are not formed as the components of capacitors, the gain Grn of the reference potential input circuit 8 with respect to the noise components induced in the reference potential detection wiring 15 containing noise components is induced in the reference potential detection wiring 15 on the basis of the capacitance value CIR of the input capacitance 128 and the capacitance value CFR of the feedback capacitance 127, which are provided in series between the reference potential detection wiring 15 and the differential amplifier 122. The gain Grn of the noise is defined by the following equation:
Grn=CFR/CIR

Here, in order to remove in-phase noise components by the differential detection circuit 7, it is necessary that the gain Gsn of noise induced in each detection wiring 113 and the gain Grn of noise induced in the reference potential detection wiring 15 be almost the same numerical value, as shown in the following equation:
Gsn=(CF/Csn)≈Grn=(CFR/CIR)

Therefore, the following is obtained:
CIR≈(CFR×Csn)/CF

In this embodiment, in order to make the feedback capacitances in the differential detection circuit 7 and the reference potential input circuit 8 to be the same value CF, a simplification is made as follows:
CIR≈Csn.

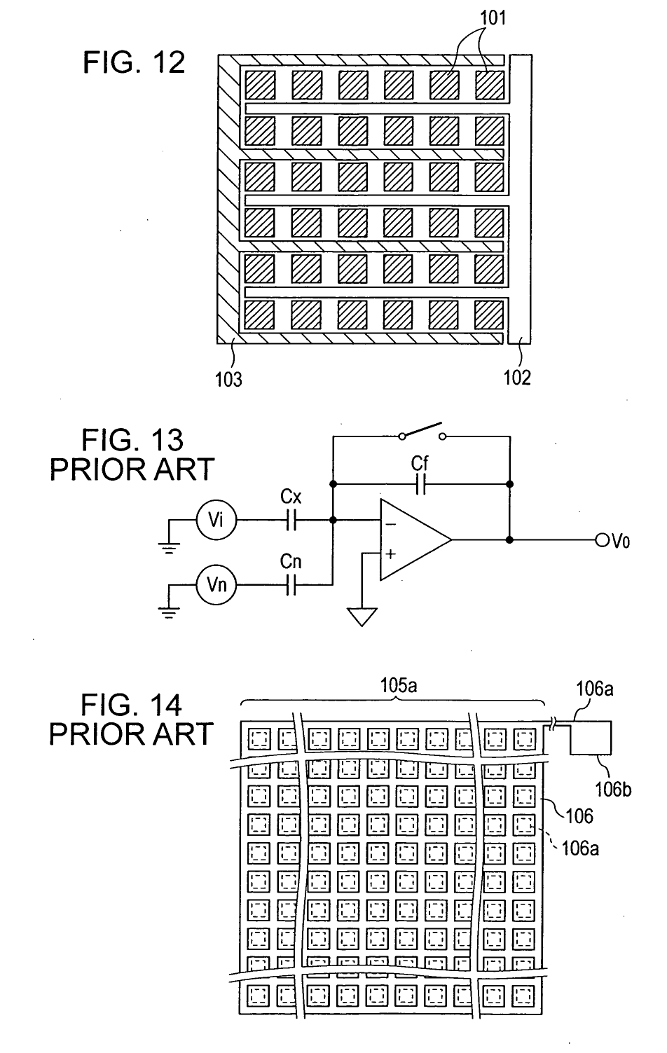

Furthermore, the detection electrodes 101, the reference electrodes 102, and the grounding electrode 103 in the sensor section 1 may be configured in such a way that, rather than being configured as shown in FIG. 1, the reference electrode 102 and the grounding electrode 103 are each formed in a comb shape so as to interdigitate the detection electrode 101, as shown in FIG. 12.

However, the substantial input capacitance Csn applied to each detection wiring 113 cannot be often calculated by only simulation because it results from the configuration of the sensor section 1 and the bypass components of the noise components. For this reason, when the capacitance value of an input capacitance 208 corresponding to the reference potential detection wiring 15 is denoted tentatively as CIR1 and the gain of noise observed after the sensor section 1 is produced is denoted as Grn1, the correction value CIR′ of the input capacitance 208 can be described by the following equation:
CIR≈(Gsn×CIR)/Grn1

Therefore, if the input capacitance 208 corresponding to the reference potential detection wiring 15 is changed to the capacitance value of the above CIR′, the gain Gsn of noise induced in the detection wiring 113 and the gain Grn of noise induced in the reference potential detection wiring 15 can be set at substantially the same.

The capacitance detection process may be performed in such a way that a program for implementing the functions of the capacitance detection circuit 100 in FIG. 5 is recorded on a computer-readable recording medium, the program recorded on the recording medium is read into the computer system, and the program is executed. The “computer system” referred to herein includes an OS (Operating System) and hardware such as peripheral devices. Furthermore, the “computer system” also includes a WWW system having a home page providing environment (or a display environment). The “computer-readable recording medium” refers to a storage device, such as a flexible disk, a magneto-optical disc, a ROM, a portable disc such as a CD-ROM, and a hard disk incorporated in the computer system. Furthermore, the “computer-readable recording medium” refers to a medium for holding a program for a fixed time, like a volatile memory (RAM) inside the computer system that serves as a server or a client when the program is transmitted via a network such as the Internet or via a communication network such as a telephone network.

The program may be transmitted from a computer system in which the program is stored in a storage device to another computer system via a transmission medium or through transmission waves in a transmission medium. The “transmission medium” for transmitting programs refers to a medium having a function for transmitting information, like a network (communication network) such as the Internet or a communication network (communication line) such as a telephone network. Furthermore, the program may implement some of the above-described functions. Furthermore, the program may implement the above-described functions by a combination with a program that has already been recorded in the computer system, that is, may be a difference file (difference program).

1. A capacitance detection circuit in which detection wirings are arranged in such a manner as to intersect a plurality of driving wirings, detection electrodes forming capacitances between the driving wirings and the detection wirings that intersect each other are formed within a sensor plane, and a capacitance change of the detection electrode, which changes due to a piece to be detected, is detected as a voltage value, the capacitance detection circuit comprising:
column wiring driving means for driving the driving wirings;
detection wiring selection means for selecting predetermined detection wiring from among a plurality of detection wirings;
a reference electrode arranged in the vicinity of the detection electrode, the reference electrode detecting the electrical potential of the piece to be detected as a reference potential; and
a capacitance computation section for determining a voltage value corresponding to the capacitance change on the basis of the reference potential and the detection potential determined from the electrical current corresponding to the capacitance of the detection electrode.

2. The capacitance detection circuit according to claim 1, wherein the detection wiring selection means selects first and second detection wirings, and the capacitance computation section comprises:
detection potential output means for differentially amplifying the current value corresponding to the capacitance of each intersection part corresponding to the first and second detection wirings and for outputting the value as the detection potential; and
computation means for determining a voltage value corresponding to the capacitance of each intersection part on the basis of the detection potential that is input in a time series manner.

3. The capacitance detection circuit according to claim 2, wherein, in a detection period, the detection wiring selection means selects reference potential detection wiring to which the reference electrode is connected as the first detection wiring and detection wiring in the vicinity of the reference potential detection wiring as the second detection wiring, and thereafter selects detection wirings in the neighborhood from among the plurality of detection wiring as first and second detection wirings, and
the computation means cumulatively adds the detection potentials that are input in a time series manner in order to determine a voltage value corresponding to the capacitance of the detection electrode.

4. The capacitance detection circuit according to claim 3, wherein, continuously to the reference potential detection wiring and the detection wiring in the neighborhood of the reference potential detection wiring selected respectively as the first and second detection wirings in the detection period, the detection wiring selection means selects detection wirings in the neighborhood in sequence as the first and second detection wirings.

5. The capacitance detection circuit according to claim 3, wherein a plurality of differential amplifiers for determining the detection potential on the basis of the electrical current flowing through the first detection wiring and the second detection wiring are provided for each detection wiring through which differential amplification is performed,
a predetermined differential amplifier determines the detection potential between the reference potential detection wiring and the first detection wiring, and
the plurality of the other differential amplifiers determine the detection potential between the detection wirings including the first detection wiring.

6. The capacitance detection circuit according to claim 5, wherein the plurality of the detection wirings are divided into a group of detection wirings, the detection wiring selection means is provided for each group of the detection wirings, and the computation means determines the voltage value corresponding to the capacitance of the detection electrode by using, as the unit, each detection wiring selected by the detection wiring selection means.

7. The capacitance detection circuit according to claim 6, wherein a plurality of the reference electrodes are provided on the sensor plane, and the reference electrodes are electrically connected to each other.

8. A capacitance detection method in which detection wirings are arranged in such a manner as to intersect a plurality of driving wirings, detection electrodes forming capacitances between the driving wirings and the detection wirings that intersect each other are formed within a sensor plane, and a capacitance change of the detection electrode, which changes due to a piece to be detected, is detected as a voltage value, the capacitance detection method comprising the steps of:
driving the driving wirings;
selecting predetermined detection wiring from among a plurality of detection wirings;
detecting the electrical potential of the piece to be detected as a reference potential by a reference electrode arranged in the neighborhood of the detection electrode; and
determining a voltage value corresponding to the capacitance change on the basis of the reference potential and the detection potential determined from the electrical current corresponding to the capacitance of the detection electrode.

9. The capacitance detection circuit according to claim 4, wherein a plurality of differential amplifiers for determining the detection potential on the basis of the electrical current flowing through the first detection wiring and the second detection wiring are provided for each detection wiring through which differential amplification is performed,
a predetermined differential amplifier determines the detection potential between the reference potential detection wiring and the first detection wiring, and
the plurality of the other differential amplifiers determine the detection potential between the detection wirings including the first detection wiring.
